(19) United States
(12) Patent Application Publication
(10) Pub. No.: US 2026/0058663 A1
(43) Pub. Date: Feb. 26, 2026

(54) Tap Delay Line Phase Detector

(71) Applicant: Mixed-Signal Devices Inc., Irvine, CA (US)

(72) Inventor: Tommy Yu, Orange, CA (US)

(73) Assignee: Mixed-Signal Devices Inc., Irvine, CA (US)

(21) Appl. No.: 19/305,668

(22) Filed: Aug. 20, 2025

Related U.S. Application Data
(60) Provisional application No. 63/685,223, filed on Aug. 20, 2024.

(51) Int. Cl. H03L 7/081; H03L 7/085; H03L 7/099; H04L 7/033

(52) U.S. Cl. CPC H03L 7/081; H03L 7/085; H03L 7/099; H04L 7/033

(57) ABSTRACT

In many embodiments of the invention, a tap delay line phase detector circuit includes a delay chain including a plurality of delay cells connected in series, each delay cell configured to introduce a predetermined time delay to a reference clock signal, a plurality of registers positioned at tap points along the delay chain, each register configured to sample a delayed version of the reference clock signal after a successive delay cell, a high-speed clock configured to provide timing signals to the plurality of registers, and a plurality of edge detectors configured to analyze outputs from the plurality of registers to determine clock transition timing, wherein the plurality of edge detectors generate edge detection signals that indicate timing relationships between the reference clock signal and the high-speed clock.

### CROSS-REFERENCE TO RELATED APPLICATIONS

This application claims priority to U.S. Application No. 63/685,223, titled Tap Delay Line Phase Detector, filed Aug. 20, 2024, which is hereby incorporated by reference in its entirety.

### FIELD OF INVENTION

The present disclosure relates to phase detection circuits for frequency synthesis systems, and more particularly to tap delay line phase detector circuits that achieves enhanced timing resolution through a delay chain architecture with multiple sampling points.

### BACKGROUND

Phase-locked loops (PLLs) represent one of the most widely adopted architectures in modern frequency synthesis applications. These systems utilize negative feedback control to enable precise frequency multiplication of reference signals by variable factors, forming the backbone of timing generation in numerous electronic systems. A typical PLL implementation comprises several interconnected components including a phase detector, loop filter, oscillator, and frequency divider.

The phase detector estimates phase differences between a reference and a feedback signal. This phase difference information drives the control mechanism that maintains frequency lock between the input reference and the output signal. The accuracy of phase detection directly influences the overall noise performance of the PLL system, with detection errors contributing to phase noise degradation that can impact system operation.

Resolution limitations in conventional phase detection approaches present ongoing challenges in achieving optimal PLL performance. Traditional digital phase detector implementations are constrained by the period of high-speed clock signals used for sampling, which establishes a fundamental limit on the minimum phase or time error that can be resolved. This resolution constraint becomes particularly problematic in applications requiring low phase noise performance, where detection accuracy directly correlates with system noise characteristics.

Current digital phase detection methods typically achieve time resolution on the order of nanoseconds, corresponding to the period of available system clocks. While this resolution may be adequate for some applications, emerging requirements for improved phase noise performance drive the need for enhanced detection capabilities. The relationship between phase detector resolution and system phase noise performance creates a direct pathway for improvement through enhanced detection precision.

The bandwidth limitations imposed by conventional digital phase detection approaches further compound these challenges. Digital loop implementations often face bandwidth restrictions that limit their ability to achieve desired noise performance characteristics. These constraints stem from the fundamental resolution limitations of existing digital phase detection architectures, creating a need for alternative approaches that can overcome these barriers while maintaining system stability and performance.

### SUMMARY

In many embodiments of the invention, a tap delay line phase detector circuit includes a delay chain including a plurality of delay cells connected in series, each delay cell configured to introduce a predetermined time delay to a reference clock signal, a plurality of registers positioned at tap points along the delay chain, each register configured to sample a delayed version of the reference clock signal after a successive delay cell, a high-speed clock configured to provide timing signals to the plurality of registers, and a plurality of edge detectors configured to analyze outputs from the plurality of registers to determine clock transition timing, wherein the plurality of edge detectors generate edge detection signals that indicate timing relationships between the reference clock signal and the high-speed clock.

In several embodiments of the invention, each delay cell includes an inverter circuit or a buffer circuit.

In some embodiments of the invention, the plurality of edge detectors includes a rising edge detector and a falling edge detector.

In further embodiments of the invention, the rising edge detector and the falling edge detector are arranged in an alternating pattern along the delay chain.

In more embodiments of the invention, the plurality of delay cells includes N delay cells each with time delay of td such that total delay N×td spans a period of the high-speed clock.

Still further embodiments of the invention also include a delay estimation circuit configured to estimate latency of the plurality of delay cells to compensate for process, voltage, and temperature variations.

In still more embodiments of the invention, the delay estimation circuit comprises a moving average filter configured to improve estimation precision of delay measurements.

In many embodiments of the invention, each tap point has more than one sampling register and where each of the more than one sampling register receives a different phase of the timing signal from the high-speed clock.

In several embodiments of the invention, a method for phase detection using a tap delay line includes passing a reference clock signal through a delay chain comprising a plurality of delay cells, each delay cell introducing a predetermined time delay, sampling delayed versions of the reference clock signal at a plurality of tap points after successive delay cells along the delay chain using a plurality of registers clocked by a high speed clock, analyzing the sampled signals using a plurality of edge detectors to identify clock transitions, and generating phase detection information based on a number of tap delays that exhibit edge transitions, wherein a phase resolution of the phase detection is determined by the predetermined time delay of individual delay cells rather than a period of the high speed clock.

In some embodiments of the invention, analyzing the sampled signals comprises alternating between rising edge detection and falling edge detection along the delay chain.

In further embodiments of the invention, even-numbered edge detectors identify rising edges and odd-numbered edge detectors identify falling edges of the sampled signals.

More embodiments of the invention also include a step of estimating latency of individual delay cells to compensate for process, voltage, and temperature variations, wherein the estimating step uses a moving average filter to improve estimation precision.

In still further embodiments of the invention a phase-locked loop system includes a tap delay line phase detector comprising a delay chain with a plurality of delay cells and a plurality of registers configured to sample delayed versions of a reference clock signal, a loop filter connected to receive phase detection signals from the tap delay line phase detector, a numerically controlled oscillator (NCO) connected to receive filtered signals from the loop filter and configured to generate an output frequency, and a frequency divider configured to divide the output frequency and provide a feedback signal to the tap delay line phase detector, wherein the tap delay line phase detector provides enhanced phase detection resolution through analysis of clock transitions at multiple tap points along the delay chain.

In still more embodiments of the invention, the tap delay line phase detector further comprises a multi-phase clock generator configured to provide multiple phases of a high-speed clock to the plurality of registers.

In many embodiments of the invention, the multi-phase clock generator provides four phases of the high-speed clock.

### BRIEF DESCRIPTION OF FIGURES

Non-limiting and non-exhaustive examples are described with reference to the following figures.

FIG. 1 illustrates a block diagram of a single-loop phase-locked loop system, according to embodiments of the invention.

FIG. 2 illustrates a tap delay line phase detector circuit with custom analog and synthesized logic sections, according to embodiments of the invention.

FIG. 3 illustrates a tap delay line implementation with multi-phase clock functionality, according to embodiments of the invention.

FIG. 4 illustrates a tap delay line implementation using two clocks with different delays, according to embodiments of the invention.

FIG. 5 illustrates a block diagram of a delay cell latency estimation circuit, according to embodiments of the invention.

FIG. 6 illustrates a delay cell latencies estimation circuit with parallel processing paths, according to embodiments of the invention.

### DETAILED DESCRIPTION

Turning now to the drawings, tap delay line phase detectors in accordance with embodiments of the invention are disclosed. Tap delay line phase detectors disclosed here can addresses the resolution limitations of conventional phase detection approaches by utilizing a delay chain architecture that achieves timing resolution substantially finer than the period of high-speed system clocks. In some embodiments, the phase detector incorporates a series of delay cells that introduce predetermined time delays to a reference clock signal, with each delay cell contributing delays on the order of picoseconds rather than nanoseconds. This architecture enables phase detection resolution that may be determined by individual delay cell characteristics rather than system clock periods, potentially providing phase noise performance improvements of 40 dB or more compared to traditional phase detection methods. The enhanced resolution capabilities may enable digital loop implementations to operate with significantly wider bandwidths, addressing the bandwidth limitations that constrain conventional phase detection systems while maintaining system stability and performance characteristics.

### Phase-locked Loop

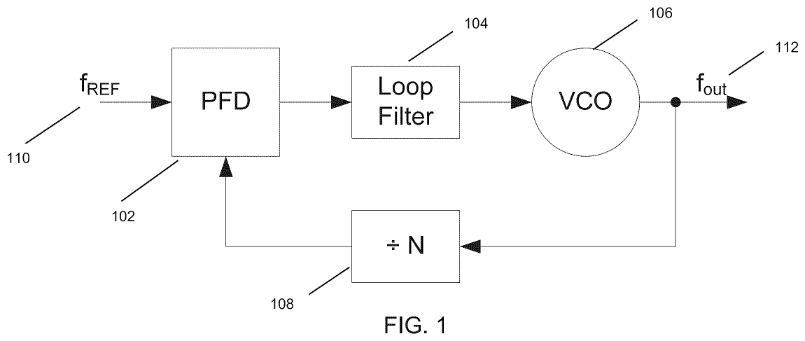

Referring to FIG. 1, a typical phase-locked loop (PLL) system provides frequency synthesis through a closed-loop feedback architecture. The PLL system includes a phase-frequency detector 102 that receives a reference frequency input 110 and compares the reference frequency input 110 with a feedback signal to generate phase difference information. A loop filter 104 connects to the phase-frequency detector 102 and processes the phase difference information to produce a control signal. The control signal drives a numerically controlled oscillator (NCO) 106, which generates an output frequency 112 based on the magnitude of the control signal. A frequency divider 108 receives the output frequency 112 and divides the output frequency 112 by a factor N to create the feedback signal that returns to the phase-frequency detector 102.

The phase-frequency detector 102 operates by estimating the phase difference between the reference frequency input 110 and the divided output frequency from the frequency divider 108. In some cases, the phase difference estimation may contain errors that contribute noise to the PLL system and affect phase noise performance. The resolution of the phase-frequency detector 102 determines the minimum phase or time error that the phase-frequency detector 102 can resolve, with higher resolution generally leading to improved system performance. The loop filter 104 may be implemented as a loop filter that smooths the output from the phase-frequency detector 102 and helps establish the loop dynamics of the PLL system.

With continued reference to FIG. 1, the numerically controlled oscillator (NCO) 106 converts the filtered control signal into an oscillating output signal at the output frequency 112. The frequency of oscillation varies in proportion to the control signal magnitude, allowing the PLL system to adjust the output frequency 112 to maintain lock with the reference frequency input 110. The frequency divider 108 performs mathematical division of the output frequency 112 by the programmable factor N, enabling frequency multiplication functionality where the output frequency 112 equals N times the reference frequency input 110 when the system achieves lock. The closed-loop configuration creates negative feedback that drives the phase error toward zero, resulting in the divided output frequency tracking the reference frequency input 110 in both frequency and phase.

The PLL system maintains lock by continuously comparing the reference frequency input 110 with the feedback signal from the frequency divider 108. When phase differences exist between these signals, the phase-frequency detector 102 generates correction signals that propagate through the loop filter 104 to adjust the numerically controlled oscillator (NCO) 106. This feedback mechanism may operate continuously to compensate for variations in the numerically controlled oscillator (NCO) 106 or changes in the reference frequency input 110. The frequency multiplication factor N can be adjusted to produce different output frequencies 112 from a single reference frequency input 110, making the PLL system suitable for various frequency synthesis applications.

### Tap Delay Line Phase Detector

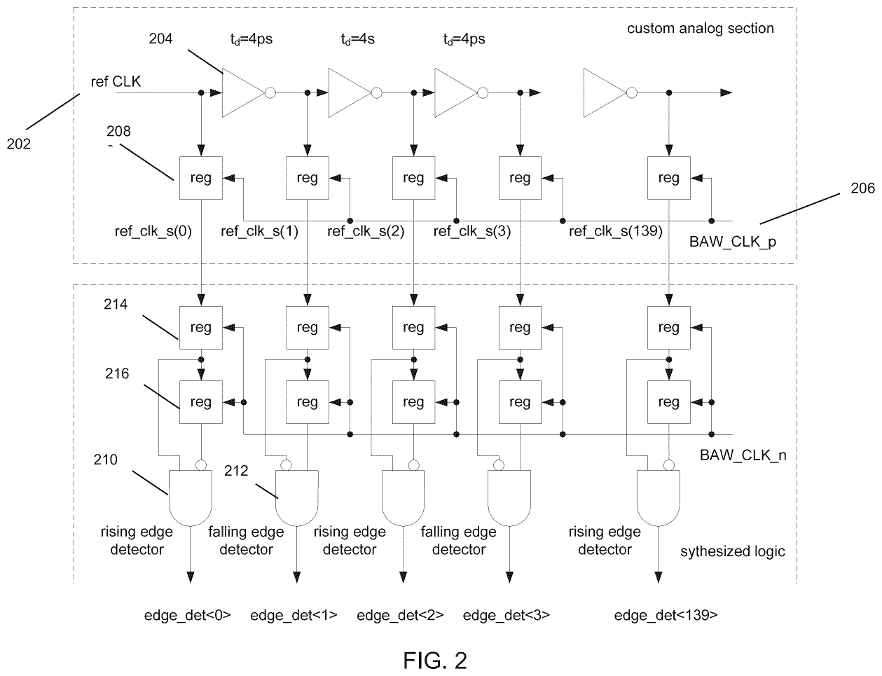

Referring to FIG. 2, a tap delay line phase detector circuit in accordance with several embodiments of the invention provides enhanced phase detection resolution through a delay chain architecture. A reference clock 202 connects to a series of N delay cells 204 arranged in a cascaded configuration, where each delay cell 204 introduces a predetermined time delay t_{d} to the reference clock 202 signal. The delay cells 204 may be implemented as inverter circuits or buffer circuits, as appropriate to the particular application. Each delay cell 204 produces a progressively delayed version of the reference clock 202, creating multiple tap points along the delay chain where the delayed signals can be sampled and analyzed.

The tap delay line circuit includes multiple corresponding sets of registers 208, 214, and 216 positioned at various tap points along the delay chain to capture the delayed reference clock signals. A high-speed clock 206 provides timing signals to the registers 208, 214, 216, enabling synchronized sampling of the delayed reference clock signals at each tap location. In certain embodiments of the invention, the high-speed clock 206 operates at a frequency of 2.5 GHz, corresponding to a period of 400 ps, which establishes the baseline timing reference for the phase detection system. The registers 208, 214, 216 latch the state of the delayed reference clock signals at specific moments determined by the high-speed clock 206, preserving the timing information for subsequent processing.

With continued reference to FIG. 2, the phase detector circuit incorporates a rising edge detector 210 and a falling edge detector 212 that analyze the latched outputs from the registers 208, 214, 216 to determine when clock transitions occur. The rising edge detector 210 identifies positive transitions in the sampled signals, while the falling edge detector 212 detects negative transitions, providing comprehensive edge detection capability across the delay line. Each delay cell 204 in the illustrated embodiment introduces a latency of 4 ps, which represents a substantial improvement in timing resolution compared to conventional digital phase detection approaches. The timing relationship between the reference clock 202 and the high-speed clock 206 may be estimated by analyzing the number of tap delays that exhibit edge transitions, as detected by the rising edge detector 210 and falling edge detector 212.

The delay line architecture reduces phase or time error resolution from the high-speed clock 206 period down to the delay of a single delay cell 204. In some cases, this reduction in resolution can provide a phase noise performance improvement of 100 times, equivalent to 40 dB of improvement over conventional digital phase detection methods. The total delay of the delay line (N×t_{d}) spans greater than one period of the high-speed clock 206, requiring approximately 100 taps to cover the complete 400 ps period when each delay cell 204 contributes 4 ps of delay. Additional taps may be incorporated beyond the minimum 100 taps to accommodate process variations and temperature variations that can affect the delay characteristics of the delay cells 204.

In the illustrated embodiment, the tap delay line phase detector system incorporates a 139-tap configuration that provides comprehensive timing coverage for high-resolution phase detection applications. The delay line spans a nominal total delay of 556 ps, with the minimum total delay exceeding one high-speed clock (BAW_CLK) period to ensure complete temporal coverage of the reference clock signal. This configuration enables the system to capture timing information across the full range of possible phase relationships between the reference clock and the system timing signals. The 139-tap arrangement provides sufficient granularity for precise phase measurements while maintaining practical implementation constraints for integrated circuit design.

The edge detection scheme within the tap delay line can employ an alternating pattern where even-numbered edge detectors identify rising edges while odd-numbered edge detectors identify falling edges of the sampled clock signals. This alternating detection pattern enables comprehensive analysis of both positive and negative clock transitions throughout the delay line, providing complete edge information for accurate phase determination. The systematic assignment of rising and falling edge detection to alternating taps ensures that the system can track clock transitions regardless of the specific timing relationship between the reference clock and the sampling clock signals. The alternating edge detection approach may enhance the overall timing resolution by capturing transition information from both edge polarities across the delay line.

With lower noise contribution from the phase detector, the PLL loop bandwidth can be increased to suppress the local oscillator (LO) phase noise. Performance enhancements achieved through the tap delay line architecture include the capability to widen the digital loop bandwidth from 100 Hz to 5 KHz through the improved 4 ps time resolution. The enhanced time resolution enables more precise phase error detection, which in turn allows the control loop to operate with higher bandwidth without compromising stability or accuracy. The 50-fold increase in loop bandwidth capability represents a substantial improvement in system responsiveness and tracking performance compared to conventional phase detection approaches. The wider bandwidth operation may enable faster lock acquisition times and improved rejection of phase disturbances while maintaining the precision timing control that characterizes high-performance frequency synthesis systems.

As further shown in FIG. 2, the systematic arrangement of registers 208, 214, 216 along the delay chain enables parallel sampling of multiple delayed versions of the reference clock 202, facilitating high-resolution phase measurements through analysis of the captured timing information. While a specific circuit implementation of a phase detector in accordance with embodiments of the invention is described above with respect to FIG. 2, one skilled in the art will recognize that alternative designs may be utilized as appropriate to a particular application.

### Multi-phase Clock Implementation

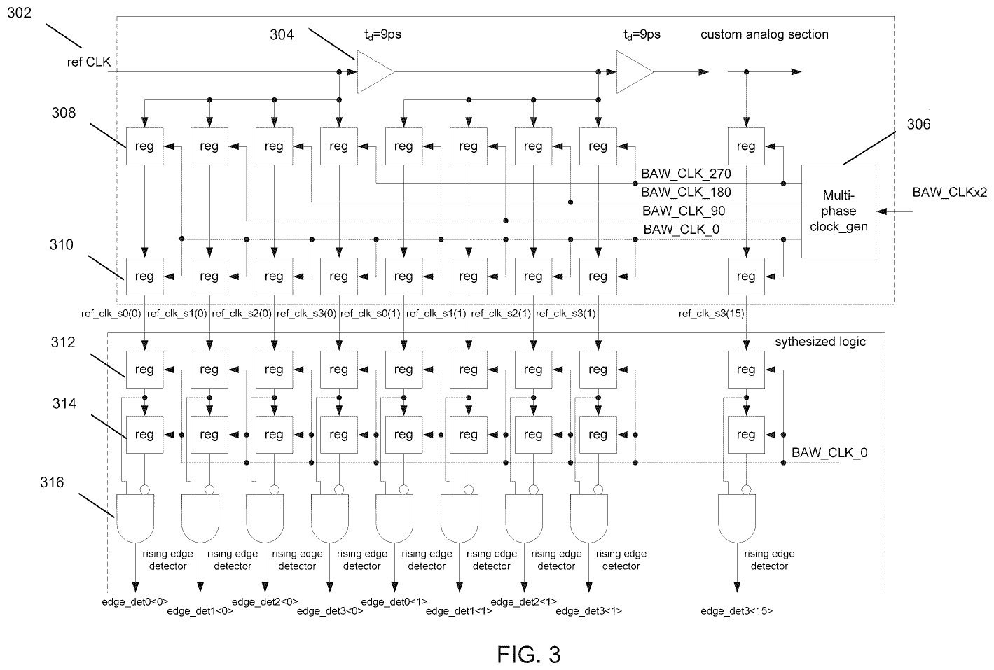

Referring to FIG. 3, an enhanced tap delay line implementation in accordance with additional embodiments of the invention incorporates a multi-phase clock generator 306 to reduce number of delay cells while maintaining phase detection performance. A reference clock 302 connects to a series of delay cells 304 arranged in a cascaded configuration, where each delay cell 304 introduces a predetermined time delay to the reference clock 302 signal. The multi-phase clock generator 306 provides four phases of a high-speed clock, which enables a reduction in the total delay requirement of the tap delay line by a factor of four compared to single-phase implementations. This multi-phase approach correspondingly reduces the number of delay cells 304 by a factor of four, resulting in a more compact and efficient circuit design.

The tap delay line circuit includes multiple hierarchical stages of registers arranged to capture and process the delayed reference clock signals. A first set of registers 308 connects to tap points along the delay chain formed by the delay cells 304, sampling the progressively delayed versions of the reference clock 302. A second set of registers 310 receives signals from the first register 308, providing additional signal processing and timing alignment. A third set of registers 312 and a fourth set of registers 314 complete the hierarchical register arrangement, with each register stage contributing to the systematic capture and analysis of timing information from the delay chain. The registers 308, 310, 312, 314 operate in coordination with the multi-phase clock signals generated by the multi-phase clock generator 306, enabling synchronized sampling across multiple clock phases.

With continued reference to FIG. 3, a rising edge detector 316 analyzes the processed signals from the register stages to identify positive transitions in the sampled reference clock 302 signals. The rising edge detector 316 receives inputs from the register chains and processes the timing information to determine when clock transitions occur relative to the multi-phase clock signals. The multi-phase clock generator 306 produces clock signals with different phase relationships, allowing the circuit to effectively sample the delayed reference clock 302 at multiple time points within each clock period. In some cases, the four-phase clock arrangement enables the tap delay line to span the same timing range as a single-phase implementation while using fewer delay cells 304, thereby reducing circuit complexity and power consumption.

The systematic arrangement of registers 308, 310, 312, 314 facilitates parallel processing of the delayed reference clock signals across multiple clock phases. Each register stage may operate on a different phase of the high-speed clock, creating temporal diversity in the sampling process that enhances the overall timing resolution of the phase detection system. The multi-phase clock generator 306 maintains precise phase relationships between the different clock signals, ensuring accurate timing measurements despite the reduced number of delay cells 304. As further shown in FIG. 3, the rising edge detector 316 can process the outputs from the register hierarchy to extract timing information that characterizes the phase relationship between the reference clock 302 and the multi-phase clock signals, enabling high-resolution phase detection with improved circuit efficiency.

While a specific circuit implementation in accordance with embodiments of the invention is described above with respect to FIG. 3, one skilled in the art will recognize that alternative designs may be utilized as appropriate to a particular application.

### Dual/multiple Clock Delay Implementation

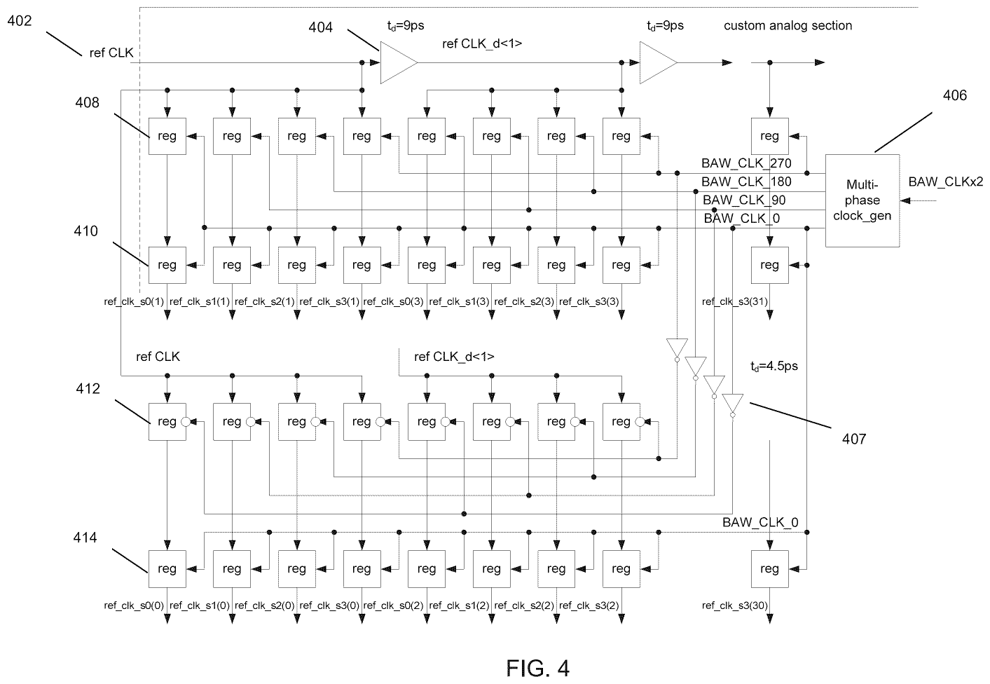

Referring to FIG. 4, an alternative tap delay line implementation in accordance with additional embodiments utilizes dual/multiple high-speed clocks with different delays to achieve enhanced phase or time error resolution. Similar to the embodiments discussed above, reference clock 402 is provided to the input of the delay line system. The delay cell latency may be limited by the technology node of the implementation, and finer phase or time error resolution can be achieved using high-speed clocks with different delays.

The delay line architecture incorporates a first set of delay cells 404 and a second set of delay cells 407 positioned at different locations within the signal chain. Each delay cell introduces a predetermined time delay to the signals passing through the respective delay cell, creating multiple delayed versions of the reference clock 402 for analysis. A multi-phase clock generator 406 produces high-speed clock signals with different delay characteristics, where the delay delta between the high-speed clocks, created by delay cell 407, sets the limit of the phase or time error resolution. The multi-phase clock generator 406 connects to various components within the system to provide synchronized timing references for the delay line operation.

With continued reference to FIG. 4, the circuit includes multiple register stages arranged to capture and process the delayed reference clock signals. A first set of registers 408 connects to receive signals from the delay line and operates in coordination with the a first set of signals from the high-speed clock 406 to sample timing information. A second set of registers 410 receives the signals from the first set of registers and are also clocked by the first set of signals from high-speed clock 406. A third set of registers 412 and a fourth set of registers 414 complete the register arrangement, with the third set of registers 412 also receiving the reference clock 402 and providing the signal to the fourth set of registers 414. The third set of registers 412 and fourth set of registers 414 are clocked by a delayed version of the clock signal 406 that is delayed by delay cells 407.

The dual/multiple clock delay implementation enables the phase or time error resolution to be determined by the delay delta between the two/more high-speed clocks rather than being constrained by individual delay cell characteristics. In some cases, this approach allows the system to achieve timing resolution that exceeds what may be possible with single-clock delay line architectures.

While a specific circuit implementation in accordance with embodiments of the invention is described above with respect to FIG. 4, one skilled in the art will recognize that alternative designs may be utilized as appropriate to a particular application.

### Delay Cell Latency Estimation Circuit

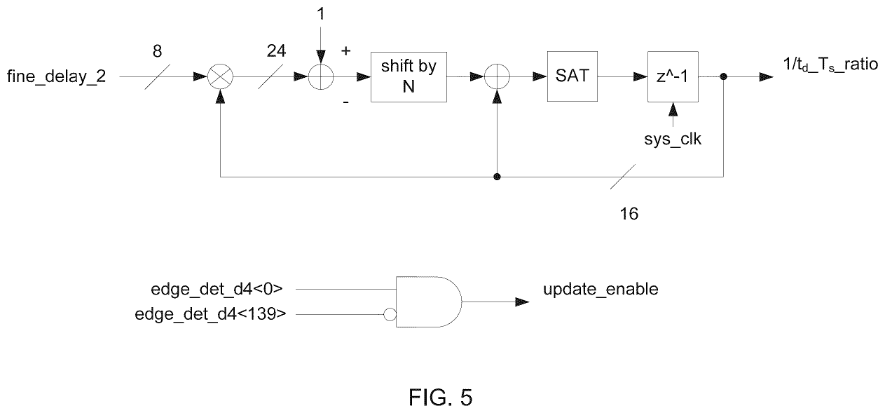

Referring to FIG. 5, a delay cell latency estimation circuit in accordance with some embodiments of the invention can be used to estimate latency of delay cells to maintain accurate phase-frequency detector resolution. The latency of the delay cells may vary over process, voltage, and temperature conditions, making continuous estimation of the delay cell timing characteristics beneficial for maintaining system performance. The system may incorporate a first-order loop estimator that updates delay estimation parameters when specific edge detection conditions are satisfied. In many embodiments of the invention, the estimator updates when edge_det_d4<0> equals 1 and edge_det_d4<139> equals 0, indicating that the delay line has captured a complete high-speed clock (BAW_CLK) period and the fine_delay_2 signal corresponds to the number of delay cells that span one high speed clock period. The conditional update mechanism ensures that delay estimates are refreshed only when valid timing information is available, preventing erroneous updates that could degrade estimation accuracy. The delay estimation circuit in FIG. 5 receives a fine_delay_2 input signal that represents coarse estimates of delay cell timing and outputs more accurate tap delay estimates with averaging.

The first-order loop estimator includes a multiplication node that receives the fine_delay_2 input signal and combines the input signal with feedback information to generate a combined signal. A shift block shifts the input signal by N bit positions to achieve the desired scaling factor for the delay estimation calculations. A saturation block receives the output from the shift block and applies saturation limits to prevent the estimation values from exceeding predetermined bounds.

With continued reference to FIG. 5, the delay estimation circuit incorporates a feedback path that creates a closed-loop configuration for the delay estimation algorithm. The feedback path includes a delay element that stores previous estimation values and routes the stored values back to the summation node for combination with new input data. The feedback path operates in coordination with a system clock signal to provide synchronized updates to the delay estimation values. The closed-loop arrangement enables the circuit to implement a moving average filtering process that improves estimation precision of the delay measurements compared to single-sample estimates.

The moving average filtering functionality operates by accumulating multiple samples of the fine_delay_2 signal over time and computing average values that reduce the impact of noise and instantaneous variations in the delay measurements. The shift block contributes to the moving average calculation by implementing the mathematical operations associated with the averaging algorithm, while the saturation block prevents the averaged values from reaching levels that could destabilize the estimation process. The feedback path maintains historical information about previous delay estimates, enabling the circuit to compute running averages that provide more stable and accurate representations of the actual delay cell latency characteristics. In some cases, the moving average filtering process may span multiple clock cycles to achieve the desired level of estimation precision for the delay cell timing parameters.

While a specific circuit implementation in accordance with embodiments of the invention is described above with respect to FIG. 5, one skilled in the art will recognize that alternative designs may be utilized as appropriate to a particular application.

### Individual Delay Cell Estimation

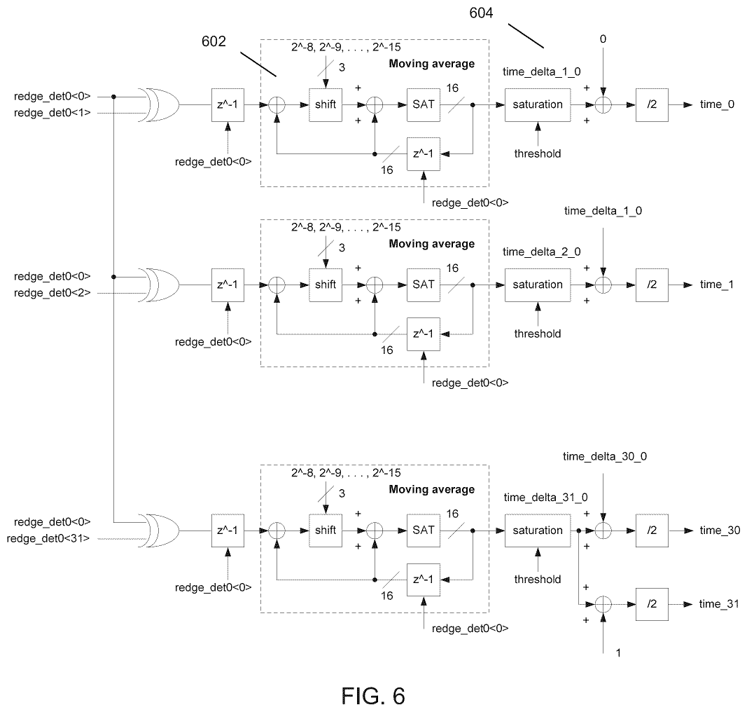

Referring to FIG. 6, an individual delay cell latencies estimation circuit in accordance with additional embodiments can address situations where latency variations exist between delay cells within the delay line architecture. The estimation circuit incorporates multiple parallel processing paths that enable separate estimation of each delay cell when the delay cells exhibit different timing characteristics due to manufacturing variations, temperature gradients, or other factors that may cause non-uniform delay behavior across the delay line. Each processing path receives redge_det0<n> signals that represent edge detection signals from the nth tap delay path, where n corresponds to specific delay cell positions within the delay chain. The redge_det0<n> signals provide timing information that characterizes the individual delay behavior of each delay cell, enabling the estimation circuit to calculate delay cell latencies in terms of the high-speed clock period for each delay cell independently.

The individual delay cell estimation circuit includes three parallel processing channels, each incorporating similar architectural elements arranged to handle multiple delay cell signals simultaneously. Each processing channel includes a moving average filter 602 that receives the redge_det0<n> input signals and processes the timing information to generate averaged delay estimates for the corresponding delay cells. The moving average filter 602 operates by accumulating multiple samples of the edge detection signals over time and computing running averages that reduce the impact of instantaneous variations and noise in the delay measurements. A threshold block 604 connects to the moving average filter 602 and applies threshold limits to the averaged delay estimates, preventing the estimation values from exceeding predetermined bounds.

With continued reference to FIG. 6, the parallel processing architecture enables the circuit to simultaneously estimate latencies for multiple delay cells without requiring sequential processing that could introduce timing delays or reduce system responsiveness. The first processing path generates an output signal labeled time_0, while the second processing path produces an output signal labeled time_1, and the third processing path creates two output signals labeled time_30 and time_31. Each processing path operates independently while sharing similar functional blocks, allowing the circuit to handle variations in delay cell characteristics across different regions of the delay line. The threshold block 604 in each processing path may apply different threshold values depending on the expected delay characteristics of the corresponding delay cells.

The systematic arrangement of parallel processing paths facilitates comprehensive delay estimation across the entire delay line while maintaining real-time operation of the phase detection system. Each moving average filter 602 may implement different averaging parameters or time constants to optimize the estimation accuracy for the specific delay cells being monitored, while the threshold block 604 provides protection against estimation values that could compromise system performance. The redge_det0<n> signals carry timing information that reflects the actual delay behavior of individual delay cells, enabling the estimation circuit to track variations in delay cell performance and adjust the phase detection calculations accordingly. In some cases, the individual delay cell estimation approach provides enhanced accuracy compared to systems that assume uniform delay characteristics across all delay cells, particularly in applications where precise timing control may be beneficial for overall system performance.

While a specific circuit implementation in accordance with embodiments of the invention is described above with respect to FIG. 6, one skilled in the art will recognize that alternative designs may be utilized as appropriate to a particular application.

Although the description above contains many specificities, these should not be construed as limiting the scope of the invention but as merely providing illustrations of some of the presently preferred embodiments of the invention. Various other embodiments are possible within its scope. Accordingly, the scope of the invention should be determined not by the embodiments illustrated, but by the appended claims and their equivalents.

1. A tap delay line phase detector circuit, comprising:
a delay chain comprising a plurality of delay cells connected in series, each delay cell configured to introduce a predetermined time delay to a reference clock signal;
a plurality of registers positioned at tap points along the delay chain, each register configured to sample a delayed version of the reference clock signal after a successive delay cell;
a high-speed clock configured to provide timing signals to the plurality of registers; and
a plurality of edge detectors configured to analyze outputs from the plurality of registers to determine clock transition timing, wherein the plurality of edge detectors generate edge detection signals that indicate timing relationships between the reference clock signal and the high-speed clock.

2. The tap delay line phase detector circuit of claim 1, wherein each delay cell comprises an inverter circuit or a buffer circuit.

3. The tap delay line phase detector circuit of claim 1, wherein the plurality of edge detectors comprises a rising edge detector and a falling edge detector.

4. The tap delay line phase detector circuit of claim 3, wherein the rising edge detector and the falling edge detector are arrang ed in an alternating pattern along the delay chain.

5. The tap delay line phase detector circuit of claim 1, wherein the plurality of delay cells includes N delay cells each with time delay of t_{d} such that total delay N×t_{d} spans a period of the high-speed clock.

6. The tap delay line phase detector circuit of claim 1, further comprising a delay estimation circuit configured to estimate latency of the plurality of delay cells to compensate for process, voltage, and temperature variations.

7. The tap delay line phase detector circuit of claim 6, wherein the delay estimation circuit comprises a moving average filter configured to improve estimation precision of delay measurements.

8. The tap delay line phase detector circuit of claim 1, where each tap point has more than one sampling register and where each of the more than one sampling register receives a different phase of the timing signal from the high-speed clock.

9. A method for phase detection using a tap delay line, comprising:
passing a reference clock signal through a delay chain comprising a plurality of delay cells, each delay cell introducing a predetermined time delay;
sampling delayed versions of the reference clock signal at a plurality of tap points after successive delay cells along the delay chain using a plurality of registers clocked by a high speed clock;
analyzing the sampled signals using a plurality of edge detectors to identify clock transitions; and
generating phase detection information based on a number of tap delays that exhibit edge transitions, wherein a phase resolution of the phase detection is determined by the predetermined time delay of individual delay cells rather than a period of the high speed clock.

10. The method of claim 9, wherein analyzing the sampled signals comprises alternating between rising edge detection and falling edge detection along the delay chain.

11. The method of claim 9, wherein even-numbered edge detectors identify rising edges and odd-numbered edge detectors identify falling edges of the sampled signals.

12. The method of claim 9, further comprising a step of estimating latency of individual delay cells to compensate for process, voltage, and temperature variations, wherein the estimating step uses a moving average filter to improve estimation precision.

13. A phase-locked loop system, comprising:
a tap delay line phase detector comprising a delay chain with a plurality of delay cells and a plurality of registers configured to sample delayed versions of a reference clock signal;
a loop filter connected to receive phase detection signals from the tap delay line phase detector;
a numerically controlled oscillator (NCO) connected to receive filtered signals from the loop filter and configured to generate an output frequency; and
a frequency divider configured to divide the output frequency and provide a feedback signal to the tap delay line phase detector, wherein the tap delay line phase detector provides enhanced phase detection resolution through analysis of clock transitions at multiple tap points along the delay chain.

14. The phase-locked loop system of claim 13, wherein the tap delay line phase detector further comprises a multi-phase clock generator configured to provide multiple phases of a high-speed clock to the plurality of registers.

15. The phase-locked loop system of claim 14, wherein the multi-phase clock generator provides four phases of the high-speed clock.
